(19) United States
(12) Patent Application Publication
(10) Pub. No.: US 2015/0270399 A1
(43) Pub. Date: Sep. 24, 2015

(54) SEMICONDUCTOR STRUCTURE AND METHOD FOR MANUFACTURING THE SAME

(71) Applicant: INSTITUTE OF MICROELECTRONICS, CHINESE ACADEMY OF SCIENCES, Beijing (CN)

(72) Inventors: Huilong Zhu, Poughkeepsie, NY (US); Qingqing Liang, Lagrangeville, NY (US); Haizhou Yin, Poughkeepsie, NY (US); Zhijiong Luo, Poughkeepsie, NY (US)

(73) Assignee: Institute of Microelectronics, Chinese Academy of Sciences, Beijing (CN)

(21) Appl. No.: 14/439,165

(22) PCT Filed: Jul. 31, 2013
(86) PCT No.: PCT/CN2013/080537

§ 371 Date: Apr. 28, 2015

(30) Foreign Application Priority Data
Nov. 6, 2012 (CN) 201210591064.4

(51) Int. Cl. H01L 29/78; H01L 21/266; H01L 29/06; H01L 21/324; H01L 21/265; H01L 29/66

(52) U.S. Cl. CPC H01L 29/7849; H01L 21/26506; H01L 29/66545; H01L 29/0649; H01L 21/324; H01L 29/6656; H01L 29/66651; H01L 21/266

(57) ABSTRACT

A method for manufacturing a semiconductor structure is disclosed. The method comprises: providing an SOI substrate, which comprises, from top to bottom, an SOI layer (100), a BOX layer (110) and a base layer (130); forming a dummy gate stack on the SOI substrate and an implantation barrier layer on both sides of the dummy gate stack; removing the dummy gate stack to form a gate recess (220); and performing, via the gate recess (220), implantation of stress inducing ions to the semiconductor structure and annealing to form, right below the gate recess (220), a stress inducing region (150) under the BOX layer (110) of the SOI substrate. Accordingly, the present invention further provides a semiconductor structure manufactured according to the above method.

The present application claims priority benefit of Chinese patent application No. 201210591064.4, filed on 6 Nov. 2012, entitled “SEMICONDUCTOR STRUCTURE AND METHOD FOR MANUFACTURING THE SAME”, which is herein incorporated by reference in its entirety.

### FIELD OF THE INVENTION

The present invention relates to the technical field of semiconductors, and particularly, to a semiconductor structure and a method for manufacturing the same.

### BACKGROUND OF THE INVENTION

With advancement in technology of manufacturing semiconductor devices, integrated circuits with higher performance and more powerful functions require greater element density, and the size of elements and the spacing among the elements need to be further downscaled. Thus, processes involved in manufacturing semiconductor devices are subject to more rigid control.

The operation speed of semiconductor devices is improved through proportionally downscaling. Channel lengths of MOS transistors have been downscaling in proportion. However, as channel lengths of MOS transistors become very short, the so-called short-channel effect (SCE) and Drain-Induced Barrier Lowering effect (DIBL) bring about significant obstacles to micromation of semiconductor devices.

Because the short-channel effect would compromise performance of devices and even make the device unable to operate properly, how to reduce the short-channel effect becomes a critical issue for research and manufacture of semiconductor devices. Mechanical stress in semiconductor devices is widely used to adjust performance of devices. It is an effective practice to reduce short-channel effect through the way of applying a stress in channels.

The conventional way of increasing stress is carried out at source/drain regions so as to generate a tensile or compressive stress in the channel. For example, in the general silicon technology, the channel of a transistor oriented to silicon {110}-crystal orientation. In such an arrangement, the hole mobility would increase when the channel is subject to a compressive stress along the direction of the channel and/or a tensile stress along the direction perpendicular to the channel, whilst the electron mobility would increase when the channel is subject to a tensile stress along the direction of the channel and/or a compressive stress along the direction perpendicular to the channel. Thus, introducing stress in the channel of a semiconductor device can effectively improve performance of the device.

Reducing short-channel effects and improving performance of devices can also be achieved by substituting an SOI substrate for a Si substrate. Silicon On Insulator (SOI) technology refers to the use of a layer of buried oxide between a top silicon layer and a substrate bulk silicon layer. Due to formation of a semiconductor thin film on an insulator, SOI materials acquire incomparable advantages over bulk silicon. For example, they are capable of achieving dielectric isolation of elements in integrated circuits, and completely eliminating parasitic latch-up effect in bulk silicon CMOS circuits. Integrated circuits made from SOI materials further exhibit such advantages as small parasitic capacitance, high density of integration, fast speed, simple process and small short-channel effect, and are particularly suitable for use in circuits of low voltage and low power consumption and so on. Accordingly, SOI is very likely to become the mainstream technology in deep sub-micron integrated circuits of low voltage and low power consumption.

Meanwhile, heterostructure of SOI makes it possible to manufacture devices with ultra-thin silicon bodies. Owing to a natural barrier of static electrons resulted from silicon dielectric interface, the ultra-thin SOI provides an alternative means to control the short-channel effect.

At present, there is a technique that is able to diminish the short-channel effect and to control power consumption through forming a ground layer under an ultra-thin buried oxide (BOX) layer in an ultra-thin SOI MOS transistor (Ultrathin-SOI MOSFET). However, the short-channel effect may be further reduced and the performance of semiconductor devices can be further improved if a stress is introduced into the semiconductor devices of such a structure.

### SUMMARY OF THE INVENTION

The present invention is intended to provide a semiconductor structure and a method for manufacturing the same, which improves performance of semiconductor devices through forming a stress inducing region in a bulk silicon layer under a buried oxide layer in an SOI substrate and introducing a favorable stress into the channel region of the semiconductor device formed in an SOI layer of an SOI substrate.

In an aspect, the present invention provides a method for manufacturing a semiconductor structure comprising:

a) providing an SOI substrate, which comprises, from top to bottom, an SOI layer (100), a BOX layer (110) and a base layer (130);
b) forming, on the SOI substrate, a dummy gate stack and an implantation barrier layer on both sides of the dummy gate stack;
c) removing the dummy gate stack to form a gate recess (220); and
d) performing, via the gate recess (220), implantation of stress inducing ions to the semiconductor structure and then annealing to form, right below the gate recess (220), a stress inducing region (150) under the BOX layer (110) of the SOI substrate.

Accordingly, the present invention further provides a semiconductor structure, which comprises:

an SOI substrate comprising, from top to bottom, an SOI layer, a BOX layer and a bulk silicon layer;

a gate stack formed on the SOI layer and comprising a gate and a gate dielectric layer;

a stress inducing region formed in the bulk silicon layer right below the gate.

The semiconductor structure and the method for manufacturing the same provided by the present invention feature, right below the gate, the formation of a stress inducing region in the bulk silicon layer under the BOX layer of the SOI substrate by means of ion implantation and annealing processes. The stress inducing region provides a favorable stress to the channels of the semiconductor device formed in the SOI layer of the SOI substrate, which accordingly improves performance of the semiconductor device.

### BRIEF DESCRIPTION OF THE DRAWINGS

Other features, aspects and advantages of the present invention are made more evident according to perusal of the following detailed description of exemplary embodiment(s) in conjunction with the appended drawings:

FIG. 1 illustrates a flowchart of an embodiment of a method for manufacturing a semiconductor structure provided by the present invention;

FIG. 2-FIG. 11 illustrate respectively cross-sectional views of a semiconductor structure manufactured at respective stages according to an embodiment of the method for manufacturing a semiconductor structure as illustrated in FIG. 1.

The same or similar reference signs in the drawings denote the same or similar elements.

### DETAILED DESCRIPTION OF THE INVENTION

Here below, the embodiments of the present invention will be described at length in conjunction with the appended drawings in order to make the objects, technical solutions and the advantages of the present invention more evident.

Embodiments of the present invention are to be described at length below, wherein examples of embodiments are illustrated in the drawings, in which throughout same or similar reference signs denote same or similar elements or elements having same or similar functions. It should be appreciated that embodiments described below in conjunction with the drawings are illustrative, and are provided for explaining the present invention only, thus they shall not be interpreted as a limit to the present invention.

Various embodiments or examples are provided here below to implement different structures of the present invention. To simplify the disclosure of the present invention, descriptions of components and arrangements of specific examples are given below. Of course, they are illustrative only and do not aim to limit the present invention. Moreover, in the present invention, reference numbers and/or letters may be repeated in different examples. Such repetition is for purposes of simplicity and clarity, which on its own does not denote any relationship between respective embodiments and/or arrangements under discussion. Furthermore, the present invention provides various examples for specific processes and materials. However, it is obvious for a person of ordinary skills in the art that other processes and/or materials may be alternatively utilized. In addition, structures where a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. It should be noted that the component(s) illustrated in the drawings might not be drawn to scale. Description of conventional components, processing technology and process are omitted herein in order not to limit the present invention unnecessarily.

The semiconductor structure provided by the present invention have various preferred structures. A preferred structure is provided and described here below.

With refer to FIG. 10, FIG. 10 illustrates a semiconductor structure comprising an SOI substrate, a ground layer 140, a gate stack, source/drain regions 160, source/drain extension regions 170, a stress inducing region 150 and an interlayer dielectric layer 250, wherein:

the SOI substrate comprises, from top to bottom, an SOI layer 100, a BOX layer 110 and a bulk silicon layer 130;

the gate stack comprises a gate 200 and a gate dielectric layer 280, wherein the gate dielectric layer 280 and the gate 200 are formed sequentially on the SOI substrate;

the source/drain regions 160 and the source/drain extension regions 170 are formed in the SOI layer 100, and the interlayer dielectric layer 250 overlays the source/drain regions 160;

the ground layer 140 is located in the bulk silicon layer 130 and under the BOX layer 110; and

the stress inducing region 150 is formed, right below the gate 200, in the bulk silicon layer 130.

In addition, sidewall spacers 210 are formed on both sides of the gate stack.

The SOI substrate is at least composed of three layers, which are: the bulk silicon layer 130, the BOX layer 110 above the bulk silicon layer 130, and the SOI layer 100 overlaying the BOX layer 110. Wherein, the material for the BOX layer 110 may be selected from a group consisting of crystalline or non-crystalline oxides, nitrides and any combination thereof. Preferably, SiO₂ is usually preferred. The material for the SOI layer 100 is monocrystalline Si, Ge or compounds of group III-V (e.g., SiC, GaAs, InAs or PIn). The SOI substrate used in the present invention is an SOI substrate having an ultra-thin SOI layer 100 and an ultra-thin BOX layer 110, wherein the thickness of the ultra-thin SOI layer is in the range of 5˜20 nm, for example, 5 nm, 15 nm or 20 nm. The thickness of the ultra-thin BOX layer 110 is in the range of 5˜30 nm, for example, 5 nm, 20 nm or 30 nm.

Optionally, isolation regions 120 may be formed in the SOI substrate to isolate the SOI layer 100 as an independent region for forming a transistor structure in subsequent processes. The material for the isolation region 120 is an insulating material, for example, selected from a group consisting of SiO₂, Si₃N₄ and any combination thereof. The width of the isolation region 120 may depend on the designing requirements of semiconductor structures.

The gate stack comprises the gate 200 and the gate dielectric layer 280. The material for the gate dielectric layer 280 may be a thermal oxide layer, including SiO₂ and Si₂N₂O, or may be a high-K dielectric. The gate 200 may comprise a gate metal layer, a gate electrode layer, a poly-Si layer or the like.

The sidewall spacer 210 may be formed with a material selected from a group consisting of Si₃N₄, SiO₂, Si₂N₂O, SiC and/or other material as appropriate. The sidewall spacer 210 may have a multi-layer structure. The sidewall spacer 210 may be formed by means of deposition-etching process, and may have a thickness in the range of around 10 nm-100 nm.

The source/drain regions 160 and the source/drain extension regions 170 are formed in the SOI layer 100 by means of ion implantation. For example, for PMOS, the source/drain regions 160 and the source/drain extension regions 170 may have P-type doping; and for NMOS, the source/drain regions 160 and the source/drain extension regions 170 may have N-type doping.

The ground layer 140 is formed in the bulk silicon layer 130 near the BOX layer 110. For example, either N-type or P-type doping may be used in case of PFET or NFET. In an embodiment of the present invention, the stress inducing region 150 may be formed in the ground layer 140 by means of carbon doping. The stress inducing region 150 is positioned in the bulk silicon layer right below the gate stack (with the BOX layer being sandwiched therebetween), which is favourable for introducing a compressive stress to the channels and thus significantly improves performance of P-type FET.

Here below, the above embodiment is to be further described in conjunction with the method for manufacturing a semiconductor structure provided by the present invention.

With reference to FIG. 1, FIG. 1 illustrates a flowchart of an embodiment of a method for manufacturing a semiconductor structure provided by the present invention. The method comprises:

step S101, an SOI substrate comprising from top to bottom an SOI layer, a BOX layer and a base layer is provided;

step S102, a dummy gate stack is formed on the SOI substrate and an implantation barrier layer is formed on both sides of the dummy gate stack;

step S103, the dummy gate stack is removed to form a gate recess;

step S104, stress inducing ions are implanted to the semiconductor structure via the gate recess and the semiconductor structure is then annealed so as to form, right below the gate recess, a stress inducing region under the BOX layer of the SOI substrate.

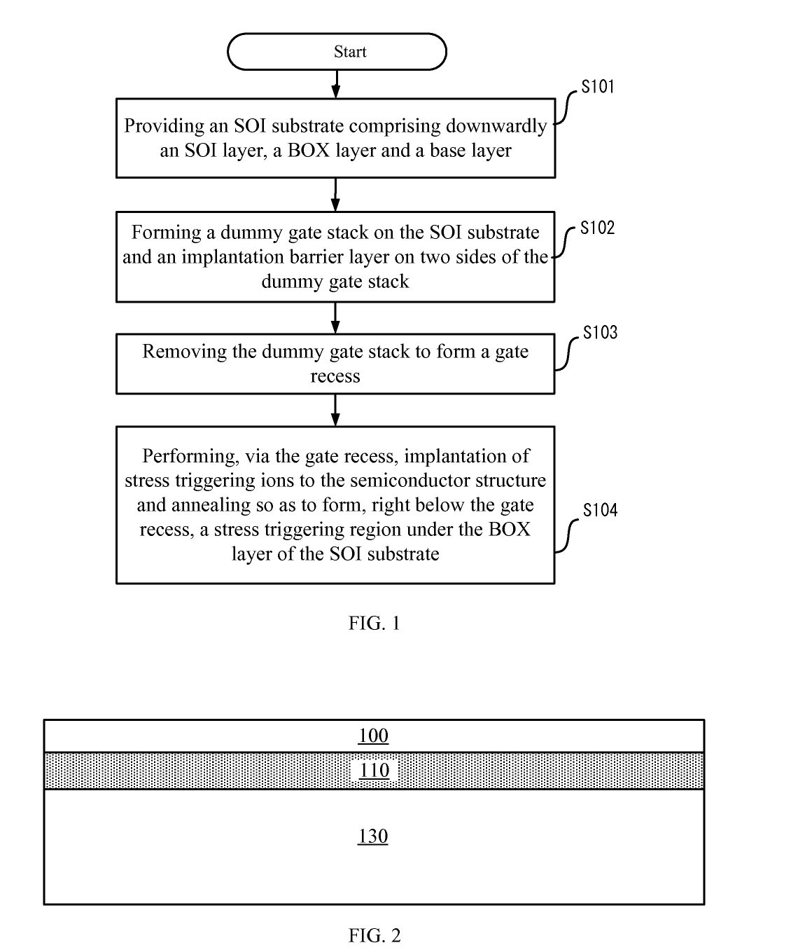

The steps S101 to S104 are to be described in conjunction with FIG. 2 to FIG. 10, which illustrate cross-sectional views of a semiconductor structure manufactured at respective stages according to an embodiment of the method for manufacturing a semiconductor structure as illustrated in FIG. 1. However, it is necessary to make it clear that the drawings for each embodiment of the present invention is exemplary only, and thus have not necessarily been drawn to the scale.

With reference to FIG. 2˜FIG. 10, the step S101 is carried out to provide an SOI substrate, which comprises a base layer, a BOX layer and an SOI layer.

Firstly, with reference to FIG. 2, the SOI substrate is at least composed of three layers: a bulk silicon layer 130, a BOX layer 110 on the bulk silicon layer 130, and an SOI layer 100 overlaying the BOX layer 110. Wherein, SiO₂ is usually selected as the material for the BOX layer 110. The material of SOI layer 100 is monocrystalline Si, Ge or compounds of group III-V (e.g., SiC, GaAs, InAs or PIn). The SOI substrate used in the present invention is an SOI substrate having an ultra-thin SOI layer 100 and an ultra-thin BOX layer 110, wherein the thickness of the ultra-thin SOI layer 100 is in the range of 5˜20 nm, for example, 5 nm, 15 nm or 20 nm; and the thickness of the ultra-thin BOX layer 110 is in the range of 5˜30 nm, for example, 5 nm, 20 nm or 30 nm.

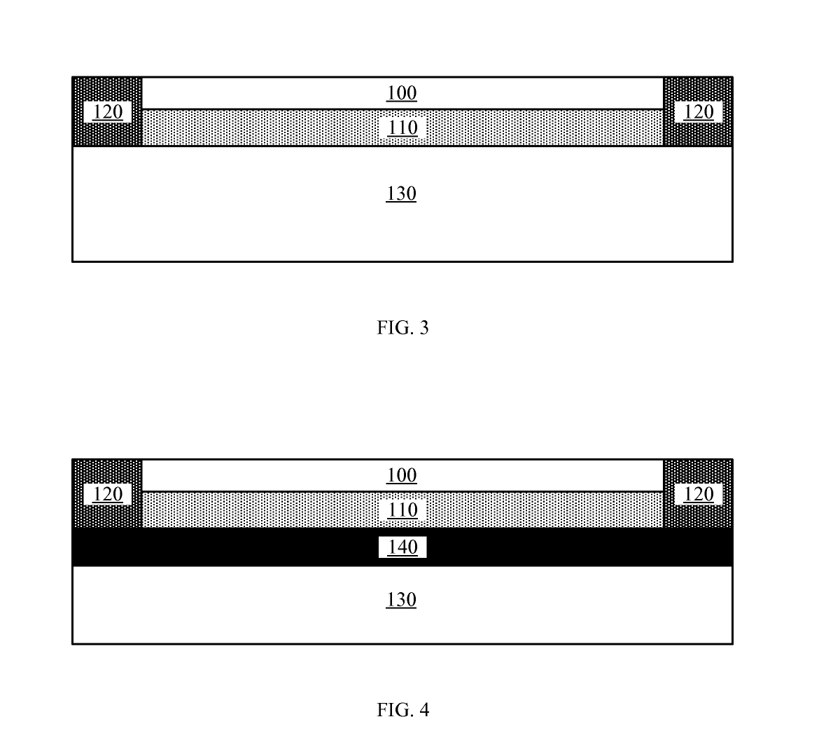

Then, an isolation region 120 is formed in the SOI substrate to isolate the SOI layer 100 as an independent region for forming a transistor structure in subsequent processes, as shown in FIG. 3. The material for the isolation region 120 is an insulating material. For example, it may be selected from a group consisting of SiO₂, Si₃N₄ and any combination thereof. The width of the isolation region 120 may depend on designing requirements of semiconductor structures.

After formation of the isolation region 120, a ground layer 140 is formed by means of ion implantation, with reference to FIG. 4. Implantation energy is controlled such that the ground layer is formed under the BOX layer 110. For example, either N-type or P-type doping may be used in the of PFET or NFET as desired. Specifically, the type of ions implanted at the step of forming the ground layer 140 depends on the type of MOSFET and the target value of the threshold voltage. If it is desirable to improve the threshold voltage of a device, P-type ions such as B (or BF₂) or In or a combination thereof may be used in case of NFET, whilst N-type ions such as As, P or a combination thereof may be used in case of PFET. If it is desirable to reduce the threshold voltage of a device, N-type ions such as As, P or a combination thereof may be used in case of NFET, whilst P-type ions such as B (or BF₂) or In or a combination thereof may be used in case of PFET.

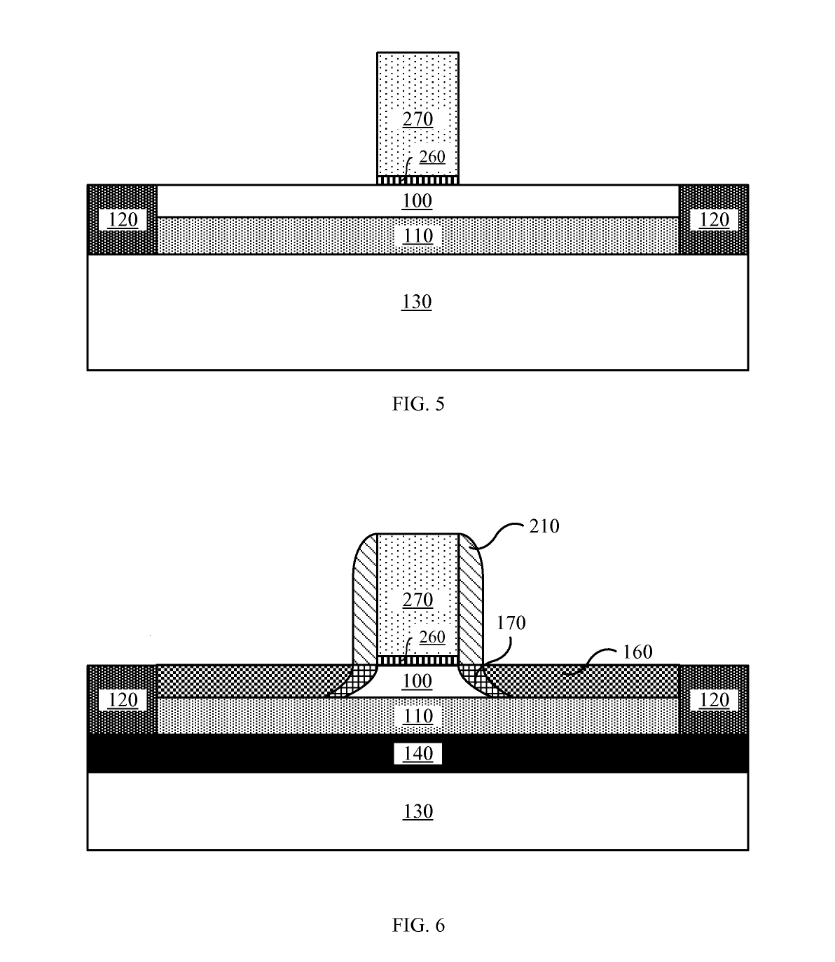

Next, the step S102 is performed to form a dummy gate stack on the SOI substrate and an implantation barrier layer on both sides of the dummy gate stack. With reference to FIG. 5, the dummy gate stack is formed on the SOI substrate (ie., on the SOI layer 100). The dummy gate stack comprises a gate dielectric layer 260 and a dummy gate 270. The dummy gate 270 may be removed by means of replacement gate process at a subsequent step to form a gate stack structure as desired. Wherein, the material for the gate dielectric layer 260 may be a thermal oxide layer, including SiO₂, SiO₂N₂, or a high-k material, for example, HfO₂, HfSiO, HfSiON, HfTaO, HfTiO, HfZrO, Al₂O₃, La₂O₃, ZrO₂, LaAlO or combinations thereof, with a thickness of about 1 nm˜10 nm. The gate dielectric layer 260 may be formed on the SOI layer 100 by means of chemical vapor deposition (CVD), high-density plasma CVD, atom layer deposition (ALD), plasma enhanced atom layer deposition (PEALD), pulse layer deposition (PLD) or any other method as appropriate. The material for the dummy gate 270 may include poly-silicon, amorphous silicon or any other material as appropriate.

After formation of the dummy gate stack, annealing may be performed to control the doping distribution of the ground layer 140 so as to adjust the switch-on voltage of the device.

After annealing is performed, source/drain extension regions 170 are formed in the SOI layer 100 by means of low-energy implantation, with reference to FIG. 6. Dopants or impurities of P-type or N-type may be implanted into the SOI layer 100. In other words, if the semiconductor device to be manufactured is NMOS, then impurities of N-type, for example, As and P, are implanted into the SOI layer 100. If the semiconductor device to be manufactured is PMOS, then impurities of P-type, for example, B and In, are implanted into the SOI layer 100. Then, annealing is performed to the semiconductor structure to activate dopants in the source/drain extension regions 170. In another embodiment, source/drain extension regions 170 may not necessarily be formed.

Usually, after formation of the source/drain extension regions 170, sidewall spacers 210 may be formed on both sides of the dummy gate stack for isolating the dummy gate stack. The material for the sidewall spacers 210 may be a material selected from a group consisting of Si₃N₄, SiO₂, Si₂N₂O, SiC and/or any other material as appropriate. The sidewall spacer 210 may have a multi-layer structure. The sidewall spacer 210 may be formed by means of deposition-etching process with a thickness in the range of around 10 nm-100 nm, for example, 30 nm, 50 nm or 80 nm.

Source/drain regions 160 may be formed after formation of the sidewall spacers 210. The source/drain regions 160 may be formed through implanting P-type or N-type dopants or impurities into the SOI layer 100. For example, the source/drain regions 160 may be P-type doped in case of PMOS, whilst the source/drain regions 160 may be N-type doped in case of NMOS. The source/drain regions 160 may be formed by means of lithography, ion implantation, diffusion and/or any other method as appropriate. In the present embodiment, the source/drain region 160 is formed in the SOI layer 100. Whilst in other embodiments, the source/drain regions 160 may be raised source/drain structures formed by means of selective epitaxial growing. The top of epitaxial portions thereof are higher than the bottom of the gate stack (herein, the bottom of the gate stack indicates the boundary between the gate stack and the SOI layer 100). Then, a thermal process such as annealing is carried out so as to activate the impurities.

An interlayer dielectric layer 250, which overlays the source/drain regions 160, the dummy gate stack, the sidewall spacers 210 and the isolation region 120, is formed on the SOI substrate. The interlayer dielectric layer 250 may be formed on the SOI substrate by means of chemical vapor deposition (CVD), high-density plasma CVD, spin coating or any other method as appropriate. The material for the interlayer dielectric layer 250 may be a material selected from a group consisting of SiO₂, carbon-doped SiO₂, BPSG, PSG, UGS, Si₂N₂O, a low-k dielectric material or combinations thereof. The thickness of the interlayer dielectric layer 250 may be in a range of 40 nm-150 nm, for example, 80 nm, 100 nm or 120 nm.

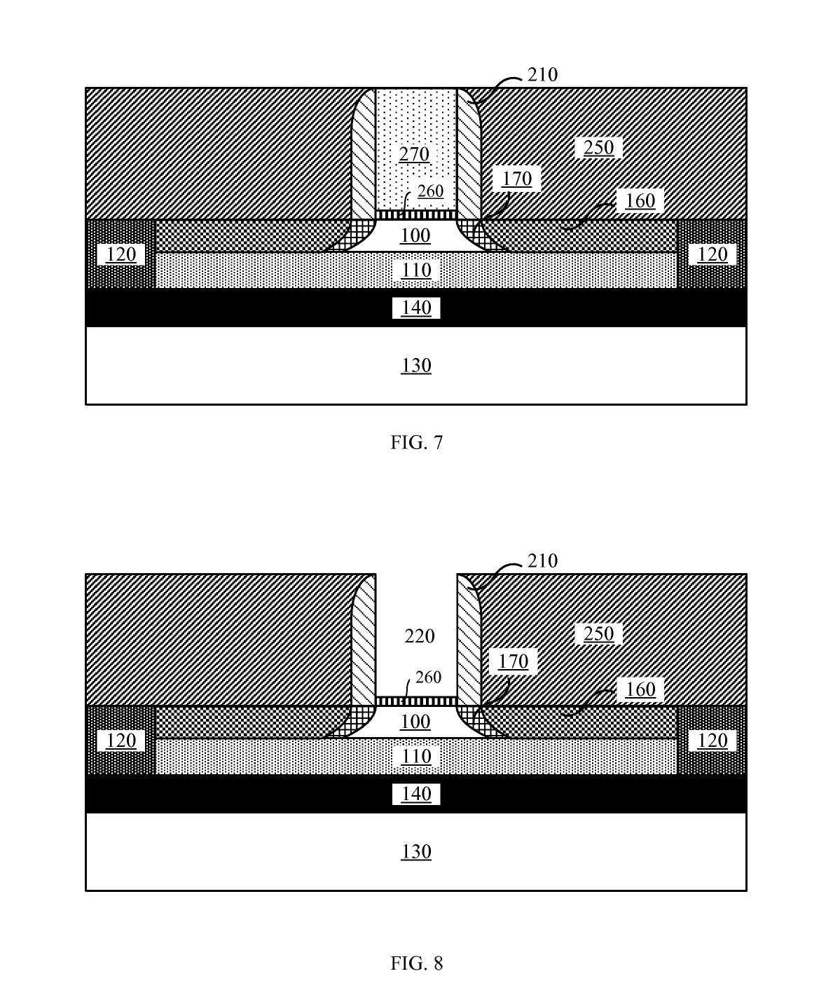

Then, the interlayer dielectric layer 250 and the dummy gate stack on the semiconductor device go through planarizing process by means of chemical-mechanical polish (CMP), as shown in FIG. 7, such that the upper surface of the dummy gate stack becomes on the same level with the upper surface of the interlayer dielectric layer 250, while the top of the dummy gate 270 and the sidewall spacers 210 are exposed. As described subsequently, the interlayer dielectric layer 250 functions as an implantation barrier layer in the subsequent process of implanting stress inducing ions.

Then, the step S103 is performed to remove the dummy gate stack to form a gate recess. The dummy gate 270 is removed to form the gate recess 220, as shown in FIG. 8. The dummy gate 270 may be removed by means of etching

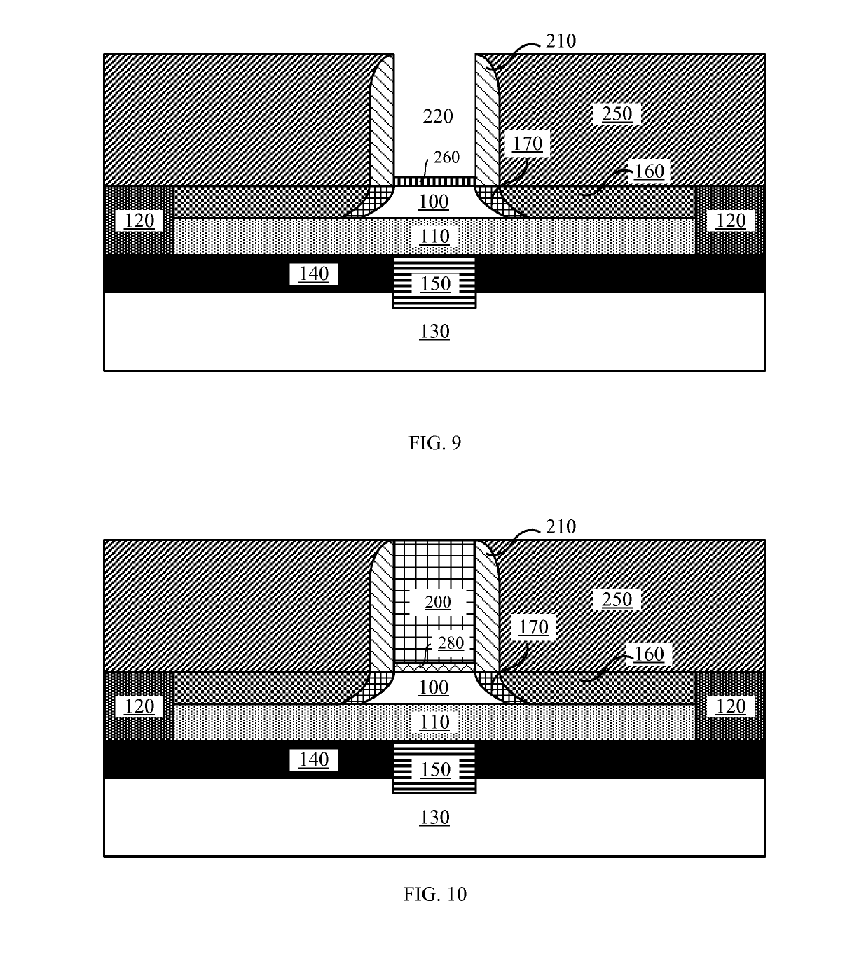

Then, the step S104 is carried out to perform implantation of stress-inducing ions and annealing to the semiconductor structure via the gate recess so as to form, right below the gate recess, a stress-inducing region under the BOX layer of the SOI substrate. With reference to FIG. 9, implantation of stress-inducing ions and annealing are performed to the semiconductor structure via the gate recess 220 so as to form, right below the gate recess, the stress-inducing region under the BOX layer of the SOI substrate. For example, carbon may be implanted through a traditional ion implantation method, and the implantation energy is accordingly controlled. At the gate recess, carbon ions would penetrate through the gate dielectric layer, the SOI layer and the BOX layer, and then enter into the bulk silicon layer below the BOX layer. Whereas at other places, carbon ions are absorbed by the interlayer dielectric layer 250, and thus the interlayer dielectric layer 250 functions as an implantation barrier layer in such an implanting process. Then, high-temperature annealing is performed to activate the carbon to form the stress-inducing region 150. For example, laser annealing, flash annealing or the like may be adopted to activate the dopants in the semiconductor structure. In an embodiment, the semiconductor structure may be annealed through instant annealing process, for example, laser annealing at a temperature of about 800˜1100° C. The annealing is also capable of repairing damage to the SOI layer, the BOX layer and the ground layer caused by carbon implantation.

The stress inducing region 150 is formed in the SOI substrate right below the gate dielectric layer 260, extends through the ground layer 140 and into the bulk silicon layer 130. The upper surface of the stress inducing region 150 is not higher than the lower surface of the BOX layer 110 of the SOI substrate. Formation of the stress-inducing region 150 is able to introduce a compressive stress into the channel regions, which can significantly improve performance of P-type semiconductor devices.

As described below, since a gate is to be formed at the place of the gate recess at a subsequent step, the stress-inducing region 150 is positioned right below the gate that is to be formed subsequently. Accordingly, the implantation of the stress inducing ions may be regarded as self-aligned.

With reference to FIG. 10, a gate is then formed at the place of the gate recess. At first, the original gate dielectric layer 260 at the gate recess is removed. Then a new gate dielectric layer 280 is formed on the SOI layer 100, and a gate metal layer 200 overlaying the new gate dielectric layer 280 is formed on the gate dielectric layer 280. Wherein the material for the gate metal layer may be one selected from a group consisting of TaC, TiN, TaTbN, TaErN, TaYbN, TaSiN, HfSiN, MoSiN, RuTa, NiTa and any combination thereof. The thickness of the gate dielectric layer 280 is in the range of 5 nm˜20 nm. The gate structure may be formed by way of depositing sequentially the gate dielectric layer 280 and the gate metal layer 200 by means of chemical vapor deposition (CVD), high-density plasma CVD, atom layer deposition (ALD), plasma enhanced atom layer deposition (PEALD), pulse laser deposition (PLD) or any other method as appropriate, and then planarizing the same.

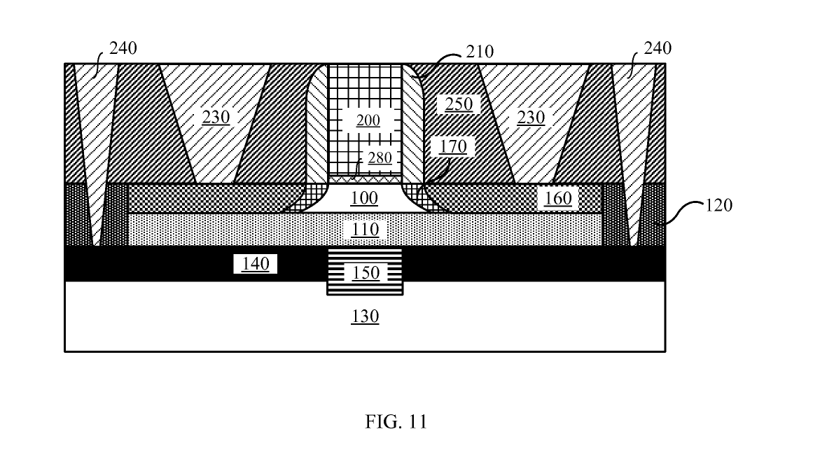

Optionally, in the semiconductor structure formed at the above steps, a first contact plug 230 and a second contact plug 240 may be further formed in order to establish an electrical connection. Specifically, the step includes: forming respectively, in the dielectric layer 250, a first contact hole that exposes at least part of the source/drain regions 160 and a second contact hole that exposes at least part of the ground layer 140. The second contact, which extends through the dielectric layer 250 and the isolation region 120, stops on the ground layer 140 and exposes at least part of the ground layer 140, whilst the first contact, which extends through the dielectric layer 250 on the source/drain regions 160, exposes at least part of the source/drain regions 160. In the process of forming the first contact hole and the second contact hole through etching the dielectric layer 250 by means of dry etching, wet etching or any other etching method as appropriate, the upper surface of the ground layer 140 may be used as the stop layer at the time of etching to form the second contact hole, whilst the upper surface of the source/drain regions 160 may be used as a stop layer at the time of etching to form the first contact hole. Accordingly, there are stop layers corresponding respectively to the etching to form the first contact hole and the second contact hole. This has lower requirements for control of the etching process, that is, difficulty in etching is lessened. In the subsequent process, a metal is filled into the first contact hole and the second contact hole to form the first contact plug 230 and the second contact plug 240, as shown in FIG. 11. Preferably, the filling metal is W. Of course, on the basis of the manufacturing requirements of semiconductors, the material for the metal may be any one selected from a group consisting of W, Al, TiAl alloy and combinations thereof

The semiconductor structure and the method for manufacturing the same provided by the present invention are intended to form a stress-inducing region in the ground layer on the ultra-thin SOI substrate, which provides a favourable stress in the channel of the semiconductor device. This can reduce the short-channel effect and significantly improve performance of the semiconductor device.

Although the exemplary embodiments and their advantages have been described in detail, it should be understood that various alternations, substitutions and modifications may be made to the embodiments without departing from the spirit of the present invention and the protection scope as defined by the appended claims. For other examples, it may be easily recognized by a person of ordinary skills in the art that the order of processing steps may be altered without departing from the protection scope of the present invention.

In addition, the scope to which the present invention is applied is not limited to the process, mechanism, manufacture, material composition, means, methods and steps of the specific embodiments described in the specification. According to the disclosure of the present invention, a person of ordinary skills in the art would readily appreciate that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the protection scope of the appended claims of the present invention includes these process, mechanism, manufacture, material composition, means, methods or steps.

What is claimed is:

1. A method for manufacturing a semiconductor structure, which comprises:
a) providing an SOI substrate, which comprises, from top to bottom, an SOI layer (100), a BOX layer (110) and a base layer (130);
b) forming, on the SOI substrate, a dummy gate stack and an implantation barrier layer on both sides of the dummy gate stack;
c) removing the dummy gate stack to form a gate recess (220);
d) performing, via the gate recess (220), implantation of stress inducing ions to the semiconductor structure and then annealing to form, right below the gate recess (220), a stress inducing region (150) located under the BOX layer (110) of the SOI substrate.

2. The method of claim 1, wherein the step a) further comprises: forming a ground layer by means of ion implantation and annealing.

3. The method of claim 1, wherein the dummy gate stack at the step b) at least comprises a dummy gate (270).

4. The method of claim 3, further comprising: forming sidewall spacers (210) on both sides of the dummy gate stack after formation of the dummy gate stack.

5. The method of claim 3, further comprising: forming source/drain regions (160) after formation of the dummy gate stack.

6. The method of claim 1, wherein the implantation barrier layer at the step b) is an interlayer dielectric layer.

7. The method of claim 1, further comprising: after the step d), forming a gate dielectric layer and a gate metal layer in the gate recess.

8. The method of claim 1, wherein the stress inducing ions are carbon ions.

9. The method of claim 1 or 8, wherein implantation of stress inducing ions is performed to the semiconductor structure in a self-aligned manner.

10. A semiconductor structure comprising:
an SOI substrate comprising, from top to bottom, an SOI layer (100), a BOX layer (110) and a bulk silicon layer (130);
a gate stack, which comprising a gate (200) and a gate dielectric layer (280), formed on the SOI layer (100); and
a stress inducing region (150) formed in the bulk silicon layer (130) right below the gate (200).

11. The semiconductor structure of claim 10, wherein the stress inducing region (150) comprises carbon ions.

12. The semiconductor structure of claim 10, wherein the bulk silicon layer (130) comprises a ground layer that is located close to the BOX layer (110).
